(19) United States
(12) Patent Application Publication
(10) Pub. No.: US 2010/0050658 A1
(43) Pub. Date: Mar. 4, 2010

(54) METHODS AND APPARATUS FOR COOLING ELECTRONIC DEVICES USING THERMOELECTRIC COOLING COMPONENTS

(75) Inventor: Ihab A. Ali, Santa Clara, CA (US)

Correspondence Address: KRAMER LEVIN NAFTALIS & FRANKEL LLP, 1177 Avenue of the Americas, New York, NY, 10036, US

(73) Assignee: Apple Inc., Cupertino, CA (US)

(21) Appl. No.: 12/241,013

(22) Filed: Sep. 29, 2008

Related U.S. Application Data
(60) Provisional application No. 61/093,117, filed on Aug. 29, 2008.

(51) Int. Cl. F25B 21/02; H05K 7/20; B23P 17/00

(52) U.S. Cl. 62/3.2; 361/688; 29/592.1

(57) ABSTRACT

An electronic device can be provided with a heat-generating component, a heat-dissipating component, and a thermoelectric cooling component. The thermoelectric cooling component may be configured to create a temperature difference between the heat-generating component and the heat-dissipating component. In some embodiments, the thermoelectric cooling component is configured to use the Peltier effect to create the temperature difference. In some embodiments, the thermoelectric cooling component may be positioned proximate to a hotspot of the heat-generating component.

### CROSS-REFERENCE TO RELATED APPLICATION

This claims the benefit of U.S. Provisional Patent Application No. 61/093,117, filed Aug. 29, 2008, which is hereby incorporated by reference herein in its entirety.

### FIELD OF THE INVENTION

This can relate to systems and methods for cooling an electronic device, and, more particularly, to systems and methods for cooling an electronic device using thermoelectric cooling components.

### BACKGROUND OF THE DISCLOSURE

As electronic components of various electronic devices (e.g., laptop computers) evolve into faster and more dynamic machines, their power requirements often consequently increase. With this increase in power consumption, an increase in power dissipation in the form of heat results. For example, in a laptop computer, chipsets and microprocessors, such as central processing units (“CPUs”) and graphics processing units (“GPUs”), are major sources of heat. Heat dissipation is an important consideration in the design of such electronic devices. If this heat is not adequately dissipated, the electronic components may fail and/or cause damage to the electronic device.

Accordingly, what is needed are systems and methods for cooling an electronic device.

### SUMMARY OF THE DISCLOSURE

Systems and methods for cooling an electronic device are provided.

According to one embodiment of the invention, there is provided an electronic device that may include a heat-generating component, a heat-dissipating component, and a thermoelectric cooling component. The thermoelectric cooling component may be configured to create a temperature difference between the heat-generating component and the heat-dissipating component.

According to another embodiment of the invention, there is provided an electronic device that may include a heat-generating component and a solid-state cooling mechanism. The solid-state cooling mechanism may include at least a first side and a second side. The solid-state cooling mechanism may be configured to move heat from the heat-generating component and through the first side to the second side.

According to yet another embodiment of the invention, there is provided a method of manufacturing an electronic device. The method may include providing a heat-generating component, providing a heat-dissipating component, and providing a thermoelectric cooling component configured to create a temperature difference between the heat-generating component and the heat-dissipating component.

According to yet still another embodiment of the invention, there is provided a method for cooling an electronic device including a heat-generating component. The method may include positioning a solid-state cooling mechanism proximate a surface of the heat-generating component, and transporting heat away from the surface of the heat-generating component with the solid-state cooling mechanism.

### BRIEF DESCRIPTION OF THE DRAWINGS

The above and other features of the invention, its nature and various advantages will become more apparent upon consideration of the following detailed description, taken in conjunction with the accompanying drawings, in which like reference characters refer to like parts throughout, and in which:

FIG. 1 shows a simplified schematic diagram of an electronic device, according to some embodiments of the invention;

FIG. 2A shows a partial cross-sectional view of a portion of the electronic device of FIG. 1, according to some embodiments of the invention;

FIG. 2B shows a partial cross-sectional view of a portion of the electronic device of FIG. 1, according to some embodiments of the invention;

FIG. 2C shows a partial cross-sectional view of a portion of the electronic device of FIG. 1, according to some embodiments of the invention;

FIG. 2D shows a partial cross-sectional view of a portion of the electronic device of FIG. 1, according to some embodiments of the invention; and

FIG. 2E shows a partial cross-sectional view of a portion of the electronic device of FIG. 1, according to some embodiments of the invention.

### DETAILED DESCRIPTION OF THE DISCLOSURE

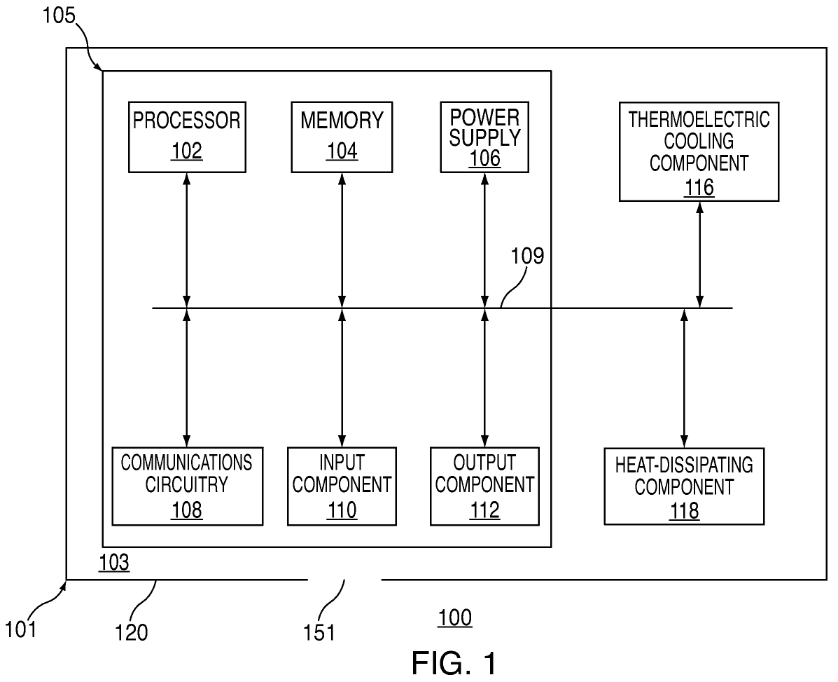

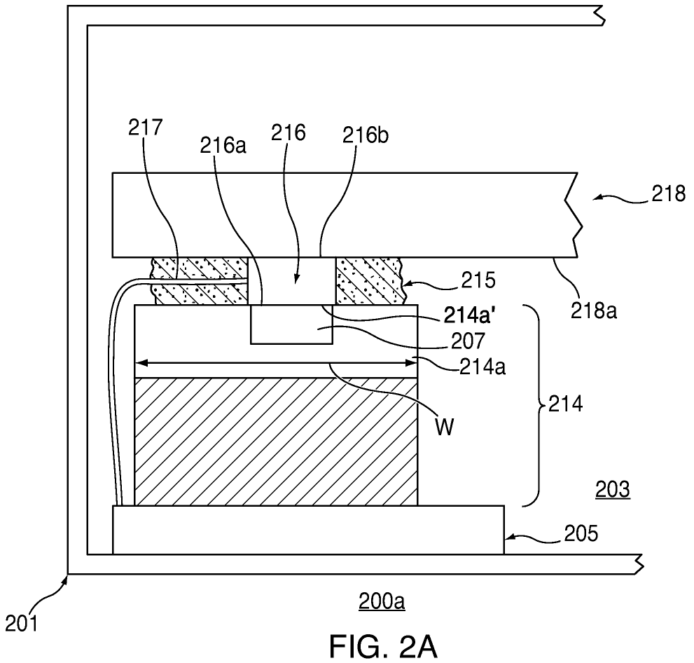

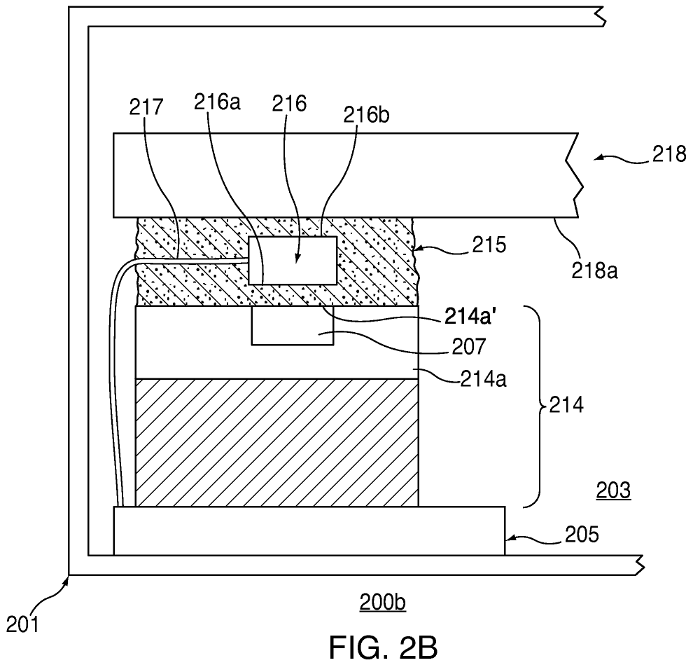

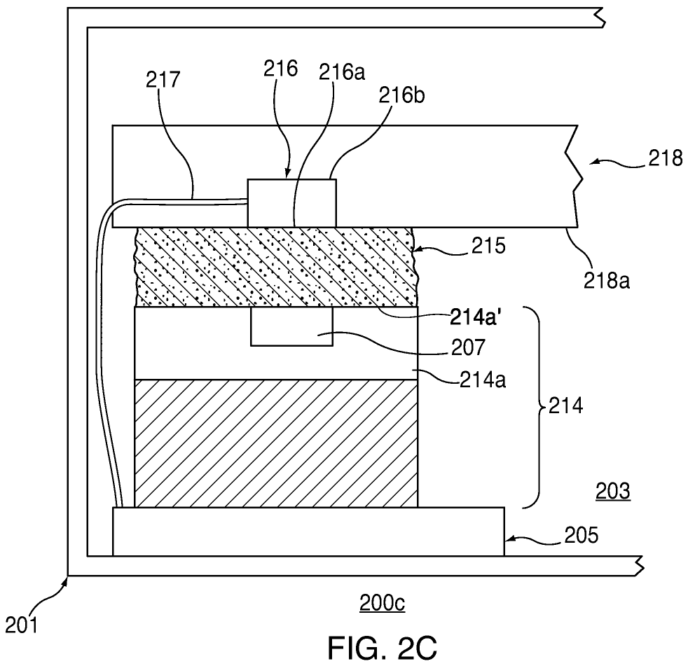

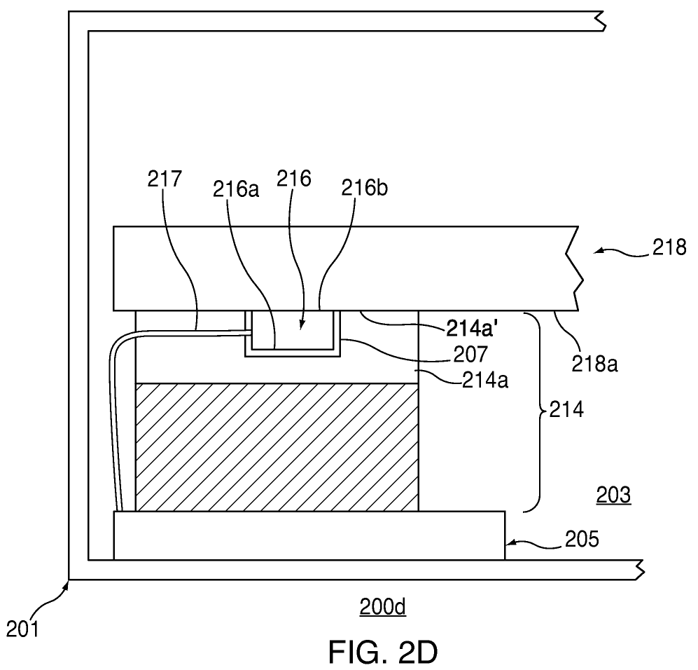

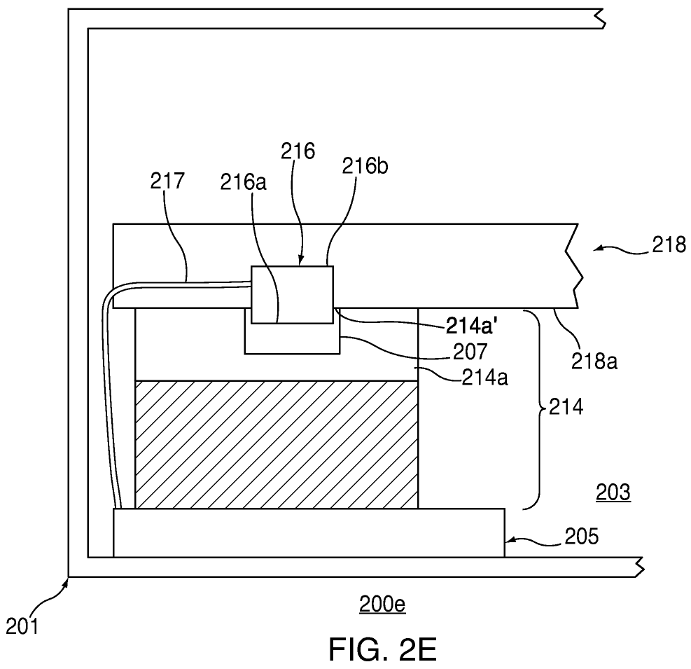

Systems and methods for cooling an electronic device using flow sensors are provided and described with reference to FIGS. 1-2E.

FIG. 1 is a simplified schematic diagram of an electronic device 100 in accordance with some embodiments of the invention. The term “electronic device” can include, but is not limited to, music players, video players, still image players, game players, other media players, music recorders, video recorders, cameras, other media recorders, radios, medical equipment, domestic appliances, transportation vehicle instruments, musical instruments, calculators, cellular telephones, other wireless communication devices, personal digital assistants, remote controls, pagers, computers (e.g., desktops, laptops, tablets, servers, etc.), monitors, televisions, stereo equipment, set up boxes, set-top boxes, boom boxes, modems, routers, keyboards, mice, speakers, printers, and combinations thereof.

As shown in FIG. 1, electronic device 100 may include housing 101, processor 102, memory 104, motherboard 105, power supply 106, communications circuitry 108, bus 109, input component 110, output component 112, thermoelectric cooling component 116, and heat-dissipating component 118. Bus 109 may include one or more wired or wireless links that provide paths for transmitting data and/or power, to, from, or between various components of electronic device 100 including, for example, processor 102, memory 104, power supply 106, communications circuitry 108, input component 110, output component 112, thermoelectric cooling component 116, and heat-dissipating component 118.

Memory 104 may include one or more storage mediums, including, but not limited to, a hard-drive, flash memory, permanent memory such as read-only memory (“ROM”), semi-permanent memory such as random access memory (“RAM”), any other suitable type of storage component, and any combinations thereof. Memory 104 may include cache memory, which may be one or more different types of memory used for temporarily storing data for electronic device applications.

Power supply 106 may provide power to the electronic components of electronic device 100. In some embodiments, power supply 106 can be coupled to a power grid (e.g., when device 100 is not a portable device, such as a desktop computer). In some embodiments, power supply 106 can include one or more batteries for providing power (e.g., when device 100 is a portable device, such as a cellular telephone or a laptop computer). As another example, power supply 106 can be configured to generate power from a natural source (e.g., solar power using solar cells).

Communications circuitry 108 may be provided to allow device 100 to communicate with one or more other electronic devices using any suitable communications protocol. For example, communications circuitry 108 may support Wi-Fi™ (e.g., an 802.11 protocol), Ethernet, Bluetooth™, high frequency systems (e.g., 900 MHz, 2.4 GHz, and 5.6 GHz communication systems), infrared, transmission control protocol/internet protocol (“TCP/IP”) (e.g., any of the protocols used in each of the TCP/IP layers), hypertext transfer protocol (“HTTP”), BitTorrent™, file transfer protocol (“FTP”), real-time transport protocol (“RTP”), real-time streaming protocol (“RTSP”), secure shell protocol (“SSH”), any other communications protocol, and any combinations thereof. Communications circuitry 108 can also include circuitry that enables device 100 to be electrically coupled to another device (e.g., a computer or an accessory device) and communicate with that other device.

One or more input components 110 may be provided to permit a user to interact or interface with device 100. For example, input component 110 can take a variety of forms, including, but not limited to, an electronic device pad, dial, click wheel, scroll wheel, touch screen, one or more buttons (e.g., a keyboard), mouse, joy stick, track ball, microphone, camera, video recorder, and any combinations thereof. Each input component 110 may be configured to provide one or more dedicated control functions for making selections or issuing commands associated with operating device 100.

One or more output components 112 can be provided to present information (e.g., textual, graphical, audible, and/or tactile information) to a user of device 100. Output component 112 can take a variety of forms, including, but not limited to, audio speakers, headphones, signal line-outs, visual displays, antennas, infrared ports, rumblers, vibrators, and any combinations thereof.

It should be noted that one or more input components 110 and/or one or more output components 112 may sometimes be referred to individually or collectively herein as an input/output (“I/O”) component or I/O or user interface. It should also be noted that one or more input components 110 and one or more output components 112 may sometimes be combined to provide a single I/O component or user interface, such as a touch screen that may receive input information through a user's touch of a display screen and that may also provide visual information to a user via that same display screen.

Processor 102 of device 100 may control the operation of many functions and other circuitry provided by device 100. For example, processor 102 can receive input signals from input component 110 and/or drive output signals through output component 112. Processor 102 may load a user interface program (e.g., a program stored in memory 104 or on another device or server) to determine how instructions received via input component 110 may manipulate the way in which information (e.g., information stored in memory 104 or on another device or server) is provided to the user via output component 112.

Motherboard 105 may be a central or primary printed circuit board (“PCB”) of electronic device 100, and may also be known as a main circuit board, mainboard, baseboard, system board, planar board, or logic board. Motherboard 105 may provide attachment points for one or more of the other electronic components of electronic device 100 (e.g., processor 102, memory 104, power supply 106, communications circuitry 108, input component 110, any external peripheral devices, etc.). Generally, most of the basic circuitry and components required for electronic device 100 to function may be onboard or coupled (e.g., via a cable) to motherboard 105. Motherboard 105 may include one or more chipsets or specialized groups of integrated circuits. For example, motherboard 105 may include two components or chips, such as a Northbridge and Southbridge. Although in other embodiments, these chips may be combined into a single component.

Housing 101 may at least partially enclose one or more of the various electronic components associated with operating electronic device 100 for protecting them from debris and other degrading forces external to device 100. In some embodiments, housing 101 may include one or more walls 120 that define a cavity 103 within which the various electronic components of device 100 can be disposed. In some embodiments, housing 101 can support various electronic components of device 100, such as I/O component 110 and/or I/O component 112, at the surfaces or within one or more housing openings 151 through the surfaces of walls 120 of housing 101. Housing openings 151 may also allow certain fluids (e.g., air) to be drawn into and discharged from cavity 103 of electronic device 100 for helping to manage the internal temperature of device 100.

In some embodiments, one or more of the electronic components of electronic device 100 may be provided within its own housing component (e.g., input component 110 may be an independent keyboard or mouse within its own housing component that may wirelessly or through a wire communicate with processor 102, which may similarly be provided within its own housing component). Housing 101 can be formed from a wide variety of materials including, but not limited to, metals (e.g., steel, copper, titanium, aluminum, and various metal alloys), ceramics, plastics, and any combinations thereof. Housing 101 may also help to define the shape or form of electronic device 100. That is, the contour of housing 101 may embody the outward physical appearance of electronic device 100.

One or more heat-dissipating components 118 can be provided to help dissipate or diffuse heat generated by the various electronic components of electronic device 100. Heat-dissipating components 118 may take various forms, including, but not limited to, heat sinks, heat spreaders, heat pipes, and any combinations thereof. For example, heat-dissipating component 118 may include any suitable thermally conductive substance, such as, for example, graphite, aluminum, magnesium, copper, an aluminum alloy, a magnesium alloy, a copper alloy, and any combinations thereof.

One or more thermoelectric cooling components 116 can be provided to create a temperature difference between the junction of two materials for helping to dissipate heat generated by the various electronic components of electronic device 100, such as described in, for example, Ali, U.S. Published Patent Application No. 2008/0101038, published May 1, 2008, entitled “Embedded Thermal-Electric Cooling Modules For Surface Spreading Of Heat,” which is incorporated by reference herein in its entirety. Each thermoelectric cooling component 116 may be any component or components suitable to move heat from one surface or material to another surface or material. For example, each thermoelectric cooling component 116 may take various forms, including, but not limited to, any solid-state cooling mechanism that uses the Peltier effect, such as a Peltier cooler, Peltier diode, Peltier heat pump, solid state refrigerator, thermoelectric cooler (“TEC”), or any other component that may transfer heat from one material to another material with the consumption of electrical energy, and any combinations thereof. A thermoelectric cooling component 116 provided as a TEC, for example, may include one or more p/n junctions (e.g., 1, 4, or 16 p/n junctions) in a semiconductor device and may be powered by providing a current from power supply 106 or motherboard 105.

Heat may be generated by one or more electronic components of electronic device 100, such as a chipset of motherboard 105, processor 102, or power supply 106. The heat may increase the temperature of an external surface of the heat-generating electronic component. If this heat is not adequately dissipated, the electronic component may fail and/or cause damage to electronic device 100. Therefore, one or more heat-dissipating components 118 may be positioned adjacent an external surface of such a heat-generating component in order to transfer the heat generated at the surface of the electronic component away from the electronic component.

However, the temperature of an external surface of a heat-generating electronic component may often vary along the surface, thereby creating one or more hotspots or concentrated areas of heat. Hotspots may degrade the performance and reliability of the heat-generating electronic components. Moreover, hotspots may reduce the effectiveness of heat-dissipating components 118 as they attempt to transfer heat away from the external surfaces of heat-generating components.

Therefore, according to some embodiments, one or more thermoelectric cooling components 116 may be positioned within cavity 103 of housing 101 to reduce the temperature provided at a portion of a surface of a heat-generating component of electronic device 100. For example, a thermoelectric cooling component 116 may be positioned proximate to one or more hotspots along a surface of a heat-generating component for transporting heat away from the hotspots. This may subdue or help suppress hotspots. By selectively cooling down specific portions of a heat-generating component, one or more thermoelectric cooling components 116 may thereby reduce leakage power of the heat-generating component.

For example, as shown in FIGS. 2A-2E, an electronic device 200 may include a housing 201 containing a heat-dissipating component 218, a thermoelectric cooling component 216, and a heat-generating electronic component 214. Heat-generating electronic component 214 may be any electronic component of electronic device 200 capable of generating heat (e.g., a chipset of motherboard 105, processor 102, power supply 106, or any other electronic component of electronic device 100 capable of generating heat). Heat-generating electronic component 214 may include an external surface portion 214a proximate an external surface 214a′. Heat-generating electronic component 214 may be configured to spread or otherwise generate heat at external surface portion 214a, thereby increasing the temperature of external surface portion 214a. The temperature of heat-generating component 214 may vary along width W of external surface portion 214a, thereby creating one or more hotspots 207.

Heat-dissipating component 218 may be positioned within cavity 203 of housing 201 such that at least a portion of heat-dissipating component 218 (e.g., external surface 218a) may be thermally coupled to heat-generating component 214 (e.g., external surface 214a′). Heat-dissipating component 218 may be configured to receive heat generated by heat-generating component 214 and to transfer the received heat away from heat-generating component 214 to another portion of cavity 203 for cooling electronic device 200.

In some embodiments, a thermal interface layer 215 may be provided between heat-dissipating component 218 and heat-generating component 214 for thermally coupling heat-dissipating component 218 and heat-generating component 214. For example, thermal interface layer 215 may be provided between external surface 218a of heat-dissipating component 218 and external surface 214a′ of heat-generating component 214. Thermal interface layer 215 may include any suitable substance that can increase the thermal conductivity of a thermal interface (e.g., by compensating for the irregular surfaces of the components exchanging heat). For example, thermal interface layer 215 may include a silicon-based grease compound, an organic-based grease compound, a thermal-grease compound, a polymer, solder, a thermal-gap pad, and any combinations thereof.

At least one thermoelectric cooling component 216 may also be positioned within cavity 203 of housing 201 such that thermoelectric cooling component 216 may be thermally coupled to both heat-generating component 214 and heat-dissipating component 218. For example, as shown in FIG. 2A-2E, thermoelectric cooling component 216 may include at least a first surface 216a thermally coupled to a portion of heat-generating component 214, such as external surface portion 214a. Moreover, thermoelectric cooling component 216 may include at least a second surface 216b thermally coupled to a portion of heat-dissipating component 218, such as external surface 218a of heat-dissipating component 218.

Thermoelectric cooling component 216 may also be coupled to a source of power (e.g., via cable 217 to a power source provided by motherboard 205) for receiving any suitable amount of power (e.g., 100 milliwatts). Thermoelectric cooling component 216 may be configured to convert an electric voltage provided by the power source into a temperature difference between first surface 216a and second surface 216b (e.g., using the Peltier effect). A current may be applied across a portion of thermoelectric cooling component 216 such that heat may be transported away from first surface 216a to second surface 216b of thermoelectric cooling component 216. For example, when a current of 100 milliamperes is applied across a portion of thermoelectric cooling component 216, thermoelectric cooling component 216 may create a temperature difference in the range of between 5° Celsius and 10° Celsius between first surface 216a and second surface 216b. This temperature difference may therefore be created between at least a portion of heat-dissipating component 218 and at least a portion of heat-generating component 214.

In some embodiments, first surface 216a of thermoelectric cooling component 216 may be physically adjacent or coupled to external surface 214a′ of surface portion 214a of heat-generating component 214, and/or second surface 216b of thermoelectric cooling component 216 may be physically adjacent or coupled to external surface 218a of heat-dissipating component 218 (see, e.g., electronic device 200a of FIG. 2A). Alternatively, at least a portion of thermal interface layer 215 may be provided between first surface 216a of thermoelectric cooling component 216 and a portion of heat-generating component 214, and/or at least a portion of thermal interface layer 215 may be provided between second surface 216b of thermoelectric cooling component 216 and heat-dissipating component 218 (see, e.g., electronic device 200b of FIG. 2B).

In yet other embodiments, at least a portion of thermoelectric cooling component 216 including second surface 216b may be at least partially embedded within a portion of heat-dissipating component 218 (e.g., in a portion of heat-dissipating component 218 having a reduced thickness). For example, as shown in FIG. 2C, thermoelectric cooling component 216 may be embedded within heat-dissipating component 218 of electronic device 200c such that first surface 216a of thermoelectric cooling component 216 is flush with external surface 218a of heat-dissipating component 218. Similarly, at least a portion of thermoelectric cooling component 216 including first surface 216a may be at least partially embedded within heat-generating component 214 (e.g., in a portion of heat-generating component 214 having a reduced thickness). For example, as shown in FIG. 2D, thermoelectric cooling component 216 may be embedded within heat-generating component 214 of electronic device 200d such that second surface 216b of thermoelectric cooling component 216 is flush with external surface 214a′ of surface portion 214a of heat-generating component 214.

In yet still other embodiments, at least a portion of thermoelectric cooling component 216 including first surface 216a may be at least partially embedded within heat-generating component 214 of electronic device 200e and at least a portion of thermoelectric cooling component 216 including second surface 216b may be at least partially embedded within a portion of heat-dissipating component 218 (see, e.g., FIG. 2E).

In some embodiments, at least a portion of thermoelectric cooling component 216 may be positioned between at least a portion of heat-dissipating component 218 and at least a portion of hotspot portion 207 of heat-generating component 214 to transport heat away from hotspot 207 (see, e.g., electronic device 200 of each of FIGS. 2A-2E). By positioning one or thermoelectric cooling components 216 proximate one or more hotspots 207 of heat-generating component 214, a uniform temperature may be influenced across external surface 214a′. This may decrease leakage power of heat-generating component 214.

While there have been described systems and methods for cooling an electronic device using thermoelectric cooling components, it is to be understood that many changes may be made therein without departing from the spirit and scope of the invention. It is also to be understood that various directional and orientational terms are used herein only for convenience, and that no fixed or absolute directional or orientational limitations are intended by the use of these words. For example, the devices of this invention can have any desired orientation. If reoriented, different directional or orientational terms may need to be used in their description, but that will not alter their fundamental nature as within the scope and spirit of this invention. Those skilled in the art will appreciate that the invention can be practiced by other than the described embodiments, which are presented for purposes of illustration rather than of limitation, and the invention is limited only by the claims which follow.

What is claimed is:

1. An electronic device comprising:
a heat-generating component;
a heat-dissipating component; and
a thermoelectric cooling component configured to create a temperature difference between the heat-generating component and the heat-dissipating component.

2. The electronic device of claim 1, wherein the thermoelectric cooling component includes at least one p/n junction.

3. The electronic device of claim 1, wherein the thermoelectric cooling component is configured to use the Peltier effect to create the temperature difference.

4. The electronic device of claim 1, wherein the temperature difference is between 5° Celsius and 10° Celsius.

5. The electronic device of claim 1 further comprising a power supply, wherein the thermoelectric cooling component is powered by the power supply.

6. The electronic device of claim 1, wherein the thermoelectric cooling component is configured to create the temperature difference using a power that is no greater than 100 milliwatts.

7. The electronic device of claim 1, wherein the thermoelectric cooling component is positioned proximate to a hotspot of the heat-generating component.

8. The electronic device of claim 1, wherein the heat-dissipating component includes at least one of graphite, aluminum, magnesium, copper, an aluminum alloy, a magnesium alloy, and a copper alloy.

9. The electronic device of claim 1 further comprising a thermal interface layer, wherein the thermal interface layer is positioned between the thermoelectric cooling component and at least one of the heat-generating component and the heat-dissipating component.

10. The electronic device of claim 9, wherein the thermal interface layer includes at least one of a silicon-based grease compound, an organic-based grease compound, a thermal-grease compound, a polymer, solder, and a thermal-gap pad.

11. The electronic device of claim 1, wherein at least a portion of the thermoelectric cooling component is embedded within the heat-generating component.

12. The electronic device of claim 11, wherein the heat-generating component includes an external surface, and wherein a surface of the thermoelectric cooling component is flush with the external surface of the heat-generating component.

13. The electronic device of claim 1, wherein at least a portion of the thermoelectric cooling component is embedded within the heat-dissipating component.

14. The electronic device of claim 13, wherein the heat-dissipating component includes an external surface, and wherein a surface of the thermoelectric cooling component is flush with the external surface of the heat-dissipating component.

15. The electronic device of claim 1, wherein the thermoelectric cooling component is configured to create the temperature difference between a first portion of the heat-generating component and a first portion of the heat-dissipating component, and wherein the electronic device further comprises a second thermoelectric cooling component configured to create a second temperature difference between a second portion of the heat-generating component and a second portion of the heat-dissipating component.

16. The electronic device of claim 1, wherein the thermoelectric cooling component is configured to decrease the leakage power of the electronic device by providing a uniform temperature across a surface of the heat-generating component.

17. An electronic device comprising:
a heat-generating component; and
a solid-state cooling mechanism having at least a first side and a second side, wherein the solid-state cooling mechanism is configured to move heat from the heat-generating component and through the first side to the second side.

18. A method of manufacturing an electronic device, the method comprising:
providing a heat-generating component;
providing a heat-dissipating component; and
providing a thermoelectric cooling component configured to create a temperature difference between the heat-generating component and the heat-dissipating component.

19. A method for cooling an electronic device, wherein the electronic device includes a heat-generating component, the method comprising:
positioning a solid-state cooling mechanism proximate a surface of the heat-generating component; and
transporting heat away from the surface of the heat-generating component with the solid-state cooling mechanism.

20. The method of claim 19, wherein the positioning comprises positioning the solid-state cooling mechanism proximate a hotspot of the surface of the heat-generating component, and wherein the transporting creates a uniform temperature along the surface of the heat-generating component.
